(19) United States
(12) Patent Application Publication
(10) Pub. No.: US 2016/0240640 A1
(43) Pub. Date: Aug. 18, 2016

(54) POWER SEMICONDUCTOR DEVICE

(71) Applicant: MITSUBISHI ELECTRIC CORPORATION, Tokyo (JP)

(72) Inventor: Katsumi NAKAMURA, Tokyo (JP)

(73) Assignee: Mitsubishi Electric Corporation, Tokyo (JP)

(21) Appl. No.: 15/027,127

(22) PCT Filed: Jan. 14, 2014
(86) PCT No.: PCT/JP2014/050415

§ 371 Date: Apr. 4, 2016

(51) Int. Cl. H01L 29/739; H01L 29/40; H01L 29/06; H01L 29/10; H01L 29/08

(52) U.S. Cl. CPC H01L 29/7397; H01L 29/1095; H01L 29/0804; H01L 29/0821; H01L 29/063; H01L 29/407

(57) ABSTRACT

A semiconductor substrate has a first surface and a second surface. A gate electrode has a part buried in a first trench. A capacitor electrode has a part buried in a second trench. An interlayer insulating film is provided on the second surface and having a first contact hole and a second contact hole. A first main electrode is provided on the first surface. A second main electrode contacts the second surface through the first contact hole and contacts the capacitor electrode through the second contact hole. The first and second trenches cross a first range of the second surface. The first and second contact holes are located only in the first range and a second range respectively of the second surface.

### TECHNICAL FIELD

The present invention relates to a power semiconductor device, more specifically, to a trench gate-type power semiconductor device.

### BACKGROUND ART

An IGBT (insulated gate bipolar transistor) is a typical principal component of a power module that handles a high voltage such as about 600 V or more, for example. In particular, a trench gate-type IGBT can reduce loss because of its low ON voltage. Meanwhile, in the trench gate-type IGBT, a saturation current density is generally large on the occurrence of abnormality leading to a load short, so that temperature increase resulting from the occurrence of the short easily causes breakdown. Thus, what is required is to reduce a saturation current while reducing an ON voltage (in other words, an ON resistance).

A technique considering the aforementioned issue as one of problems to be solved is disclosed in International Publication No. 02/058160 (patent document 1). This document discloses a trench gate-type IGBT including a gate electrode buried in a trench for a gate and a “conductive layer for an emitter” buried in a trench for an emitter. In this IGBT, an emitter potential is applied not only to an emitter region in a semiconductor substrate but also to the “conductive layer for an emitter.” A hole (contact hole) provided in an interlayer insulating film for application of the potential is shared between the emitter region and the “conductive layer for an emitter.”

### PRIOR ART DOCUMENT

### Patent Document

Patent Document 1: International Publication No. 02/058160

### SUMMARY OF INVENTION

### Problems to be Solved by Invention

The technique of the aforementioned document is capable of reducing a saturation current density to some extent while reducing an ON voltage. However, an ON voltage is an important feature that directly affects power loss, so that further improvement on the ON voltage has been desired.

The present invention has been made to solve the aforementioned problem. It is an object of the present invention to provide a power semiconductor device capable of reducing a saturation current density while reducing an ON voltage.

### Means of Solving Problems

A power semiconductor device according to the present invention includes a semiconductor substrate, a first main electrode, a trench insulating film, a gate electrode, a capacitor electrode, an interlayer insulating film, and a second main electrode. The semiconductor substrate has a first surface and a second surface opposite the first surface. The semiconductor substrate includes a first region having a first conductivity type, a second region provided on the first region and having a second conductivity type different from the first conductivity type, and a third region provided on the second region and arranged in the second surface and having the first conductivity type. The second surface is provided with a plurality of first trenches and a plurality of second trenches. The first trenches face the first to third regions. The first main electrode is provided on the first surface of the semiconductor substrate. The trench insulating film covers the first trenches and the second trenches of the semiconductor substrate. The gate electrode has parts buried in the first trenches with the trench insulating film therebetween. The capacitor electrode has parts buried in the second trenches with the trench insulating film therebetween. The interlayer insulating film is provided on the second surface and has a first contact hole and a second contact hole. The second main electrode is provided on the interlayer insulating film. The second main electrode contacts the third region through the first contact hole and contacts the capacitor electrode through the second contact hole. The second surface of the semiconductor substrate has a first range in one direction on the second surface and a second range out of the first range toward the one direction. Each of the first trenches and each of the second trenches cross the first range in the one direction. Regarding the first and second ranges, the first contact hole is located only in the first range and the second contact hole is located only in the second range.

### Advantageous Effect of Invention

According to the power semiconductor device of the present invention, the second contact hole provided for potential application to the capacitor electrode is arranged out of the first range corresponding to a range where an effective gate structure is formed. This can reduce a saturation current density while reducing an ON voltage.

These and other objects, features, aspects and advantages of the present invention will become more apparent from the following detailed description and the accompanying drawings.

### BRIEF DESCRIPTION OF DRAWINGS

FIG. 1 is a plan view schematically showing the structure of a power semiconductor device according to an embodiment of the present invention.

FIG. 2A is a partial plan view schematically showing a dashed area II in FIG. 1.

FIG. 2B is a partial plan view schematically showing the structure of a lower part of FIG. 2A.

FIG. 2C is a partial plan view schematically showing the structure of a lower part of FIG. 2B.

FIG. 2D is a partial plan view schematically showing the structure of a lower part of FIG. 2C.

FIG. 2E is a partial plan view schematically showing the positions of contact holes in FIG. 2B.

FIG. 3 is a schematic partial sectional view taken along line in each of FIGS. 2A to 2D.

FIG. 4 is a schematic partial sectional view taken along line IV-IV in each of FIGS. 2A to 2D.

FIG. 5A shows a result of a simulation about a current potential in an ON state according to Comparative Example 1 conducted in a region corresponding to a dashed area V of FIG. 3.

FIG. 5B shows an example of a result of a simulation about a current potential in an ON state according to Working Example conducted in the dashed area V of FIG. 3.

FIG. 6 shows profiles of a carrier concentration of electrons and holes in an ON state, and a doping concentration in each of a direction D in FIG. 3 of Working Example, a direction of Comparative Example 1 corresponding to the direction D in FIG. 3, and a direction E (FIG. 11) of Comparative Example 2.

FIG. 7 is a graph showing a relationship between a collector-emitter voltage V_{CE}and a collector current density J_{C} in each of Working Example (solid line), Comparative Example 2 (alternate long and short dashed line), and Comparative Example 3 (dashed line).

FIG. 8 is a graph showing a relationship of a damping trench capacitor ratio with each of a saturation current density J_{C}(sat), an ON voltage V_{CE}(sat), a maximum interrupt gate voltage pulse width t_{w}, and a maximum interrupt energy density E_{SC} in Working Example.

FIG. 9 is a graph showing a relationship between the ON voltage V_{CE}(sat) and a trench pitch W_{TP} in Working Example.

FIG. 10 is a graph showing a relationship between the ON voltage V_{CE}(sat) and turn-off loss E_{OFF} in each of Working Example (solid line) and Comparative Example 2 (dashed line).

FIG. 11 is a partial sectional view showing the structure of a power semiconductor device according to Comparative Example 2.

### DESCRIPTION OF EMBODIMENT(S)

(Structure)

An embodiment of the present invention is described below based on the drawings. In the drawings, identical or corresponding parts are identified by the same reference number and will not be described repeatedly.

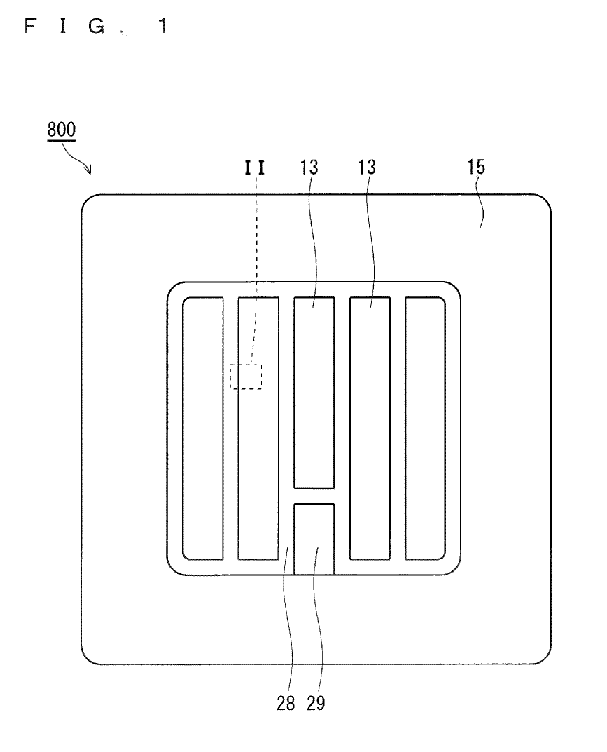

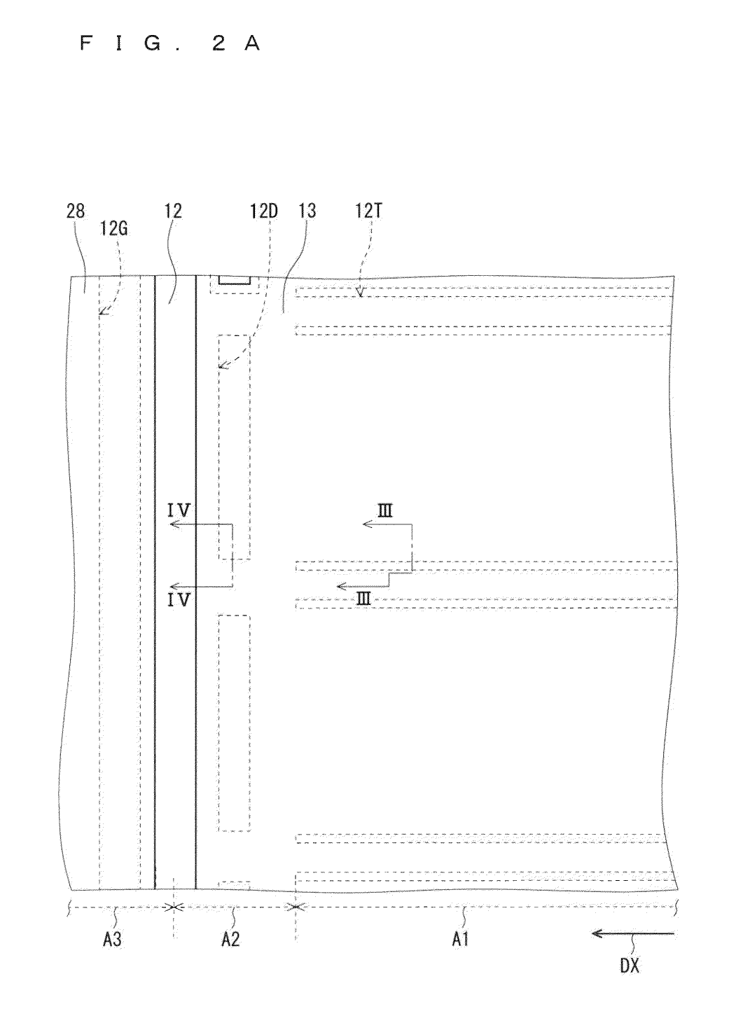

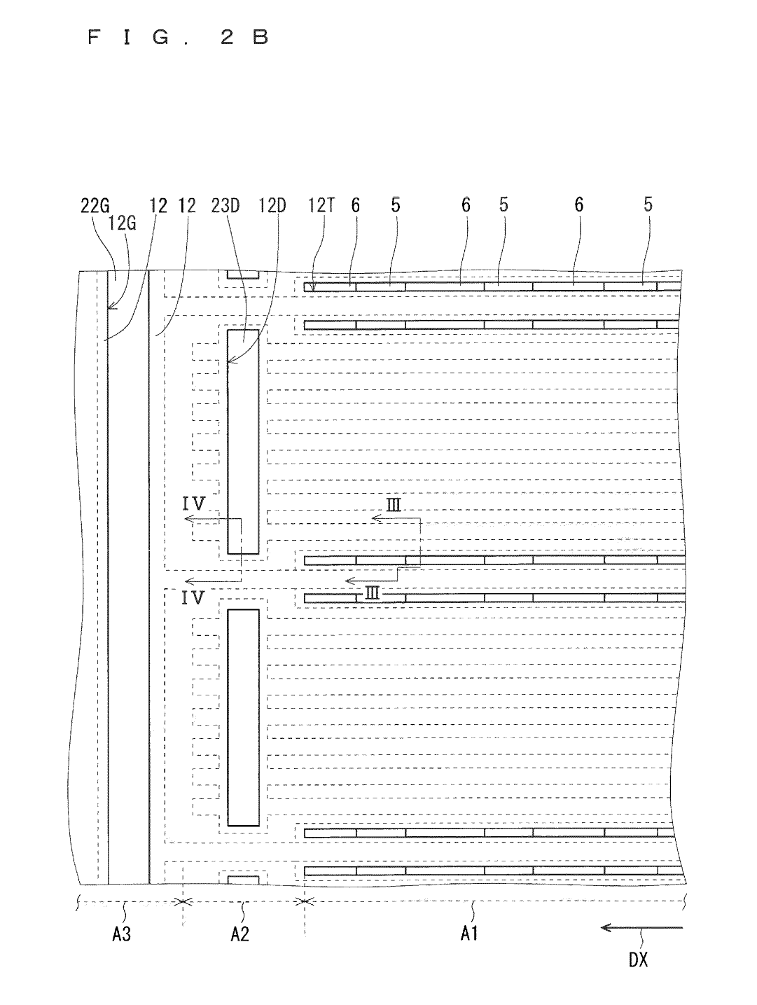

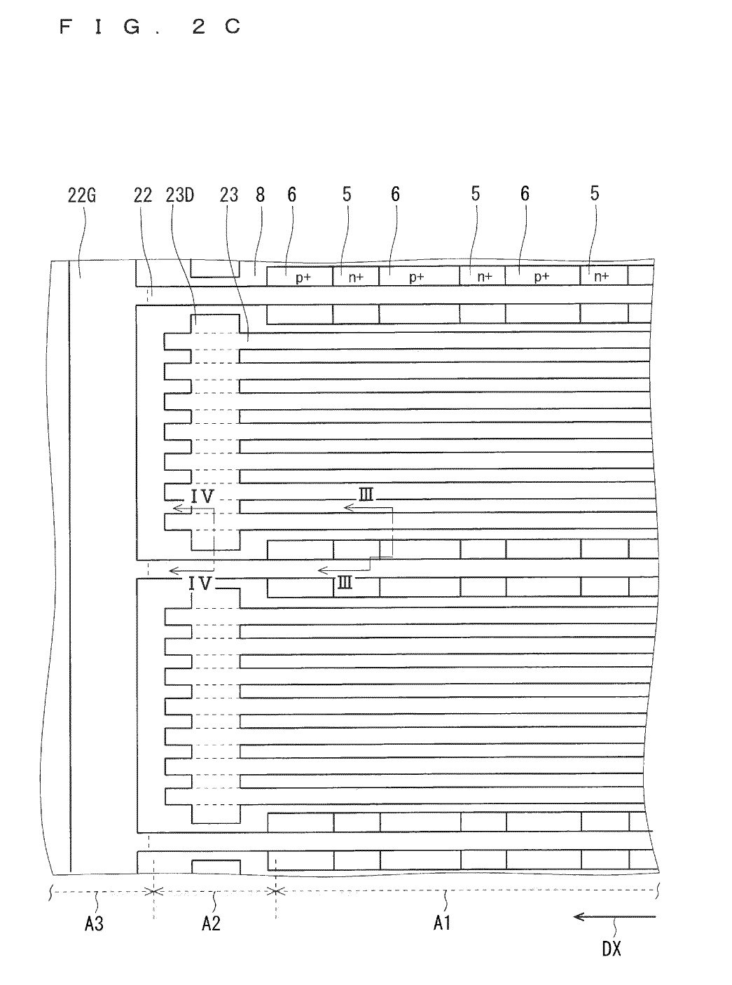

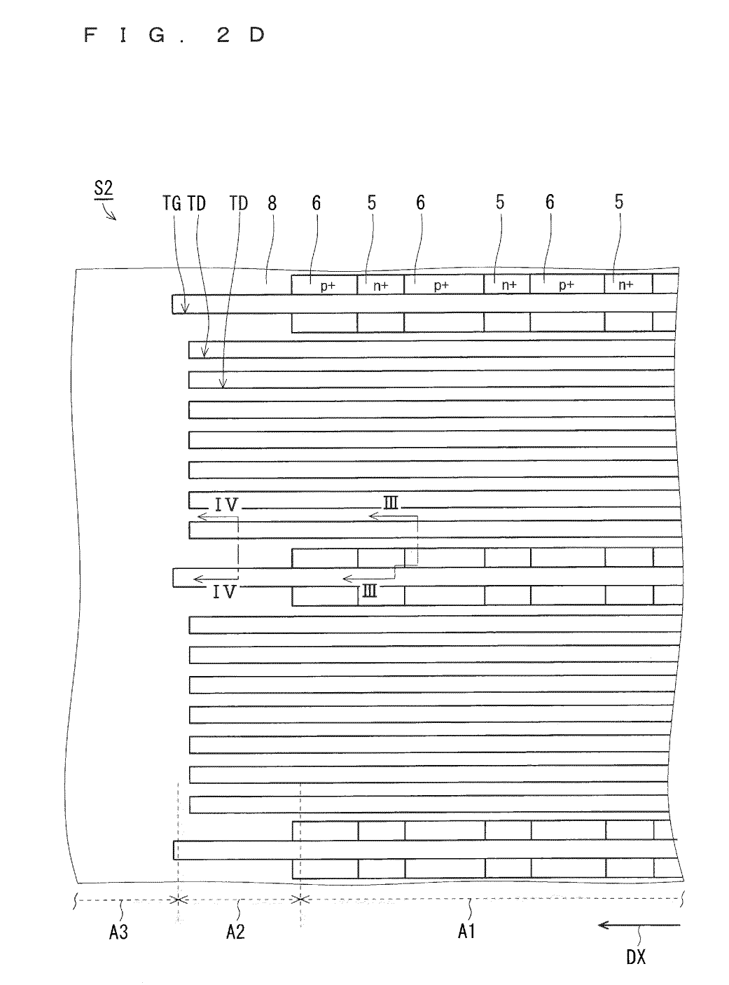

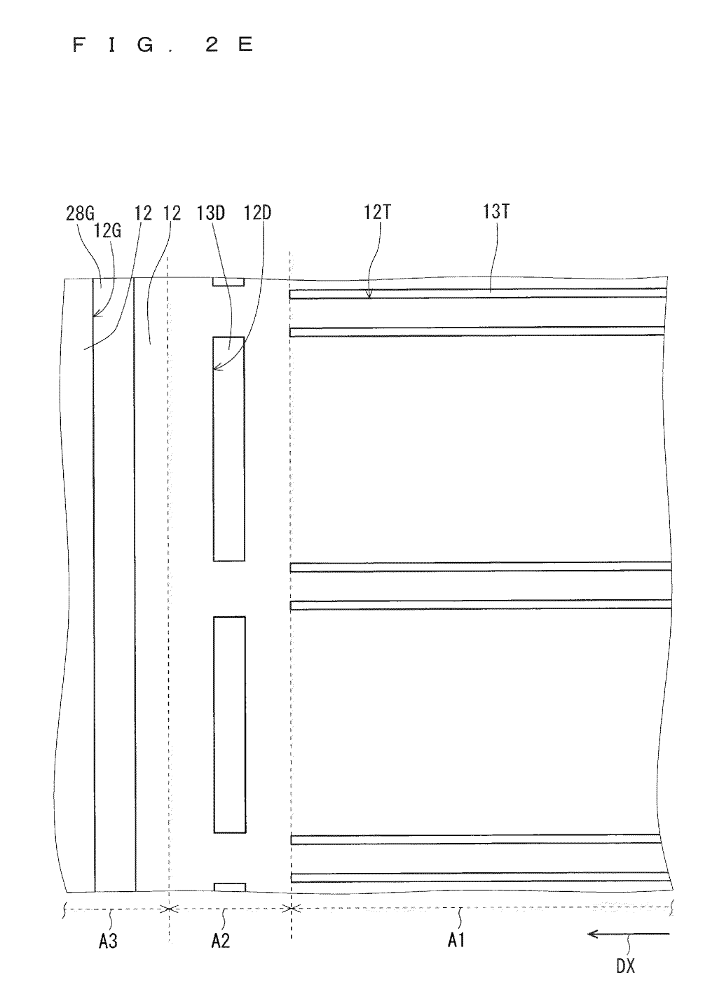

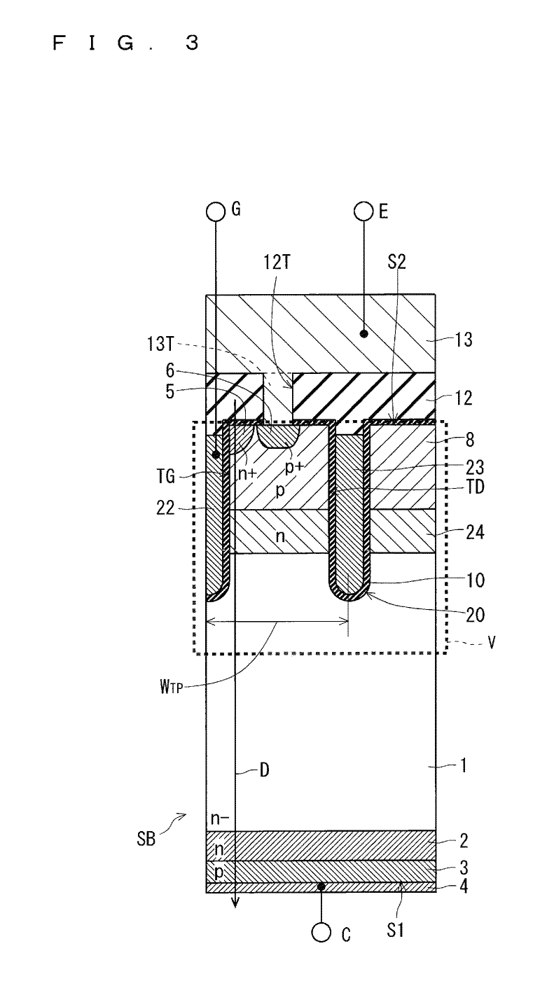

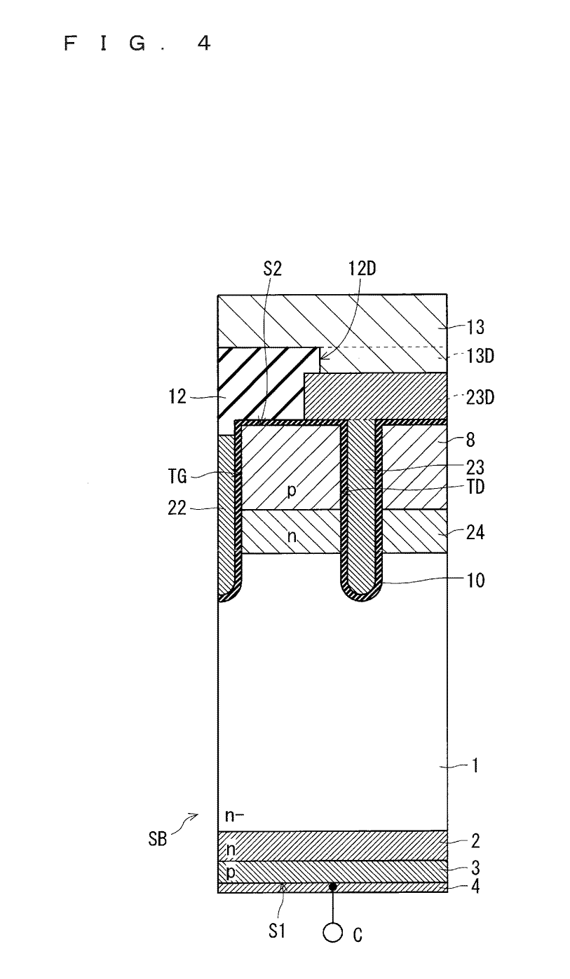

FIG. 1 is a plan view schematically showing the structure of a trench gate-type IGBT 800 (power semiconductor device) according to the embodiment. FIG. 2A shows a dashed area II in FIG. 1. FIGS. 2B to 2D each schematically show the structure of a lower part of FIG. 2A. FIG. 2E shows the positions of contact holes in an interlayer insulating film in the field of view of each of FIGS. 2A to 2D. FIGS. 3 and 4 are schematic partial sectional views taken along line and line IV-IV respectively in each of FIGS. 2A to 2D.

The IGBT 800 includes a substrate SB (semiconductor substrate), a collector electrode 4 (first main electrode), a trench insulating film 10, a gate electrode 22, a capacitor electrode 23, an interlayer insulating film 12, an emitter electrode 13 (second main electrode), a surface gate wiring part 28 (gate wiring part), a gate pad 29, and a passivation layer 15. The substrate SB (FIGS. 3 and 4) has a lower surface 51 (first surface) and an upper surface S2 (second surface opposite the first surface). The upper surface S2 (FIG. 2D) is provided with a plurality of gate trenches TG (first trenches) and a plurality of damping trenches TD (second trenches). The trenches in a group including both the gate trenches TG and the damping trenches TD may be equally spaced with a pitch W_{TP} (FIG. 3) in a pitch direction (a direction orthogonal to a direction DX in FIG. 2D).

The substrate SB includes an n⁻-drift layer 1 (first region), a p-base layer 8, an n⁺-emitter layer 5, an n-buffer layer 2, a p-collector layer 3, a p⁺-layer 6, and an n-layer 24 (first region). In this embodiment, the substrate SB is made of silicon (Si).

The n⁻-drift layer 1 has an n-type (first conductivity type) and an impurity concentration from about 1×10¹² to about 1×10¹⁵ cm⁻³, for example. The n⁻-drift layer 1 can be prepared by using an FZ wafer manufactured by floating zone (FZ) process. In this case, a part of the substrate SB except the n⁻-drift layer 1 can be formed by ion implantation and annealing technique. The n-layer 24 is provided between the n⁻-drift layer 1 and the p-base layer 8. The n-layer 24 has the n-type and an impurity peak concentration higher than the impurity concentration in the n⁻-drift layer 1. The impurity peak concentration in the n-layer 24 is from about 1×10¹⁵ to about 1×10¹⁷ cm⁻³, for example. The n-layer 24 reaches a depth position in the substrate SB viewed from the upper surface S2 deeper than the depth position of the p-base layer 8 by from about 0.5 to about 1.0 μm, for example. The n⁻-drift layer 1 and the n-layer 24 form a region (first region) having the n-type.

The p-base layer 8 (second region) is provided on the region (first region) including the n⁻-drift layer 1 and the n-layer 24. In this embodiment, the p-base layer 8 is provided directly on the n-layer 24. The p-base layer 8 reaches a depth position in the substrate SB viewed from the upper surface S2 deeper than the depth position of the n⁺-emitter layer 5 and shallower than the depth position of the n-layer 24. The p-base layer 8 has a p-type (second conductivity type different from the first conductivity type) and an impurity peak concentration from about 1×10¹⁶ to about 1×10¹⁸ cm⁻³, for example.

The n⁺-emitter layer 5 (third region) is provided on the p-base layer 8 and arranged in the upper surface S2. The n⁺-emitter layer 5 has a depth from about 0.2 to about 1.0 μm, for example. The n⁺-emitter layer 5 has the n-type and an impurity peak concentration from about 1×10¹⁸ to about 1×10²¹ cm⁻³, for example.

The p⁺-layer 6 is provided on the p-base layer 8 and arranged in the upper surface S2. The p⁺-layer 6 has a surface impurity concentration from about 1×10¹⁸ to about 1×10²¹ cm⁻³, for example. The p⁺-layer 6 preferably reaches a depth position in the substrate SB viewed from the upper surface S2 same as or deeper than the depth position of the n⁺-emitter layer 5.

The n-buffer layer 2 is provided between the n⁻-drift layer 1 and the p-collector layer 3. The n-buffer layer 2 has an impurity peak concentration from about 1×10¹⁵ to about 1×10¹⁷ cm⁻³, for example. The n-buffer layer 2 reaches a depth position in the substrate SB viewed from the lower surface 51 from about 1.5 to about 50 μm, for example.

The p-collector layer 3 is provided on the lower surface 51 of the substrate SB. The p-collector layer 3 has the p-type and a surface impurity concentration from about 1×10¹⁶ to about 1×10²⁰ cm⁻³, for example. The p-collector layer 3 reaches a depth position in the substrate SB viewed from the lower surface 51 from about 0.3 to about 1.0 μm, for example.

As shown in FIG. 3, the gate trench TG (first trench) has a side wall that faces each of the n⁻-drift layer 1 and the n-layer 24 (first region), the p-base layer 8, and the n⁺-emitter layer 5. The damping trench TD (second trench) has a side wall that faces each of the n⁻-drift layer 1, the n-layer 24, and the p-base layer 8 in this embodiment. The trench insulating film 10 covers the gate trench TG and the damping trench TD in the substrate SB.

The gate electrode 22 (FIG. 3) has a part buried in the gate trench TG with the trench insulating film 10 therebetween. The gate electrode 22 faces the p-base layer 8 between the n⁺-emitter layer 5 and the n-layer 24 (first region) while the trench insulating film 10 is interposed between the gate electrode 22 and this p-base layer 8. The capacitor electrode 23 has a part buried in the damping trench TD with the trench insulating film 10 therebetween. The provision of the capacitor electrode 23 reduces a saturation current density in the IGBT 800 and suppresses an oscillation phenomenon of a gate voltage to be caused on the occurrence of a short of a load of the IGBT 800.

The gate electrode 22 has a gate connection 22G (FIG. 2C) through which parts of the gate electrode 22 buried in at least adjacent two of the gate trenches TG are connected to each other. The parts of the gate electrode 22 buried in the gate trenches TG and the gate connection 22G are preferably made integrally using the same material.

The capacitor electrode 23 (FIG. 2C) has a capacitor connection 23D (FIG. 2C) through which parts of the capacitor electrode 23 buried in at least adjacent two of the damping trenches TD (FIG. 2D) are connected to each other. As a result, electrical paths to the damping trenches TD can be put together. The parts of the capacitor electrode 23 buried in the damping trenches TD and the capacitor connection 23D are preferably made integrally using the same material.

As shown in FIGS. 2A to 2E, the upper surface S2 of the substrate SB has a range A1 (first range) in the direction DX (one direction) on the upper surface S2, a range A2 (second range) out of the range A1 toward the direction DX, and a range A3 (third range) out of the range A2 toward the direction DX. As shown in FIGS. 2D and 2E, each of the gate trench TG and the damping trench TD cross the range A1 in the direction DX. The gate trench TG extends from the range A1 into the range A3 through the range A2.

The damping trench TD (FIG. 2D) has an end portion located in the range A2. This can prevent the capacitor electrode 23 (FIG. 2C) buried in the damping trench TD from contacting the gate connection 22G. In this way, a short between the capacitor electrode 23 and the gate electrode 22 can be prevented.

The interlayer insulating film 12 (FIGS. 3 and 4) are provided on the upper surface S2. The emitter electrode 13 and the surface gate wiring part 28 (FIG. 1) are provided on the interlayer insulating film 12. The interlayer insulating film 12 (FIG. 2B) has an MOS area contact hole 12T (first contact hole), a damping trench area contact hole 12D (second contact hole), and a gate contact hole 12G (third contact hole). The emitter electrode 13 contacts the n⁺-emitter layer 5 and the p⁺-layer 6 through the MOS area contact hole 12T. Further, the emitter electrode 13 contacts the capacitor connection 23D of the capacitor electrode 23 through the damping trench area contact hole 12D. The MOS area contact hole 12T and the damping trench area contact hole 12D are isolated from each other.

The surface gate wiring part 28 (FIG. 2A) contacts the gate connection 22G (FIG. 2B) of the gate electrode 22 through the gate contact hole 12G located in the range A3. This can form contact with the gate electrode 22 while bypassing the damping trench TD located in the ranges A1 and A2.

The MOS area contact hole 12T (FIG. 2B) extends along the gate trench TG (specifically, in the direction DX). The MOS area contact hole 12T is provided on the n⁺-emitter layer 5 and the p⁺-layer 6. An MOS area contact 13T (FIGS. 2E and 3) of the emitter electrode 13 is buried in the MOS area contact hole 12T. The MOS area contact 13T contacts each of the n⁺-emitter layer 5 and the p⁺-layer 6.

As shown in FIG. 2B, the damping trench area contact hole 12D preferably extends in a direction crossing the direction DX, more preferably, in a direction orthogonal to the direction DX. The damping trench area contact hole 12D is arranged on the capacitor connection 23D. A damping contact 13D (FIGS. 2E and 4) of the emitter electrode 13 is buried in the damping trench area contact hole 12D. The damping contact 13D contacts the capacitor connection 23D. In this structure, connections to the parts of the capacitor electrode 23 buried in corresponding ones of the plurality of damping trenches TD (FIG. 2D) can be formed collectively.

The gate contact hole 12G (FIG. 2B) preferably extends in a direction crossing the direction DX, more preferably, in a direction orthogonal to the direction DX. The gate contact hole 12G is arranged on the gate connection 22G. A gate contact 28G (FIG. 2E) of the surface gate wiring part 28 (FIG. 2A) is buried in the gate contact hole 12G. The gate contact 28G contacts the gate connection 22G.

As shown in FIG. 2E, etc., regarding the ranges A1 and A2, the MOS area contact hole 12T is located only in the range A1 while the damping trench area contact hole 12D is located only in the range A2. This prevents overlap of the MOS area contact hole 12T and the damping trench area contact hole 12D in terms of their positions in the direction DX. The gate contact hole 12G is located in the range A3.

The collector electrode 4 (FIGS. 3 and 4) is provided on the lower surface S1 of the substrate SB. The collector electrode 4 contacts the p-collector layer 3.

(Advantageous Effect)

According to this embodiment, the damping trench area contact hole 12D (FIG. 2E) provided for potential application to the capacitor electrode 23 (FIG. 2C) is arranged out of the range A1. This allows the capacitor electrode 23 to have a potential different from that of the emitter electrode 13 (FIG. 2A) in the range A1 (FIG. 2C) corresponding to a range where an effective gate structure is formed, while the capacitor electrode 23 has a potential same as that of the emitter electrode 13 in a place directly below the damping trench area contact hole 12D in the range A2. In this way, interrupt capability can be enhanced during turn-off operation while an ON voltage is reduced. The following describes consideration conducted to verify this advantageous effect.

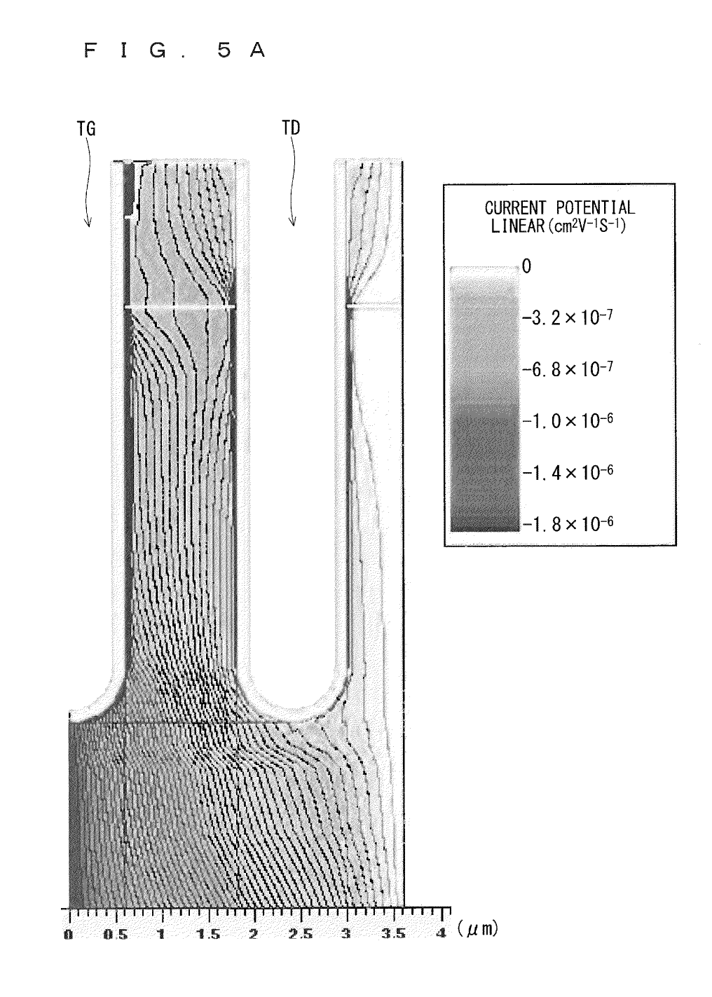

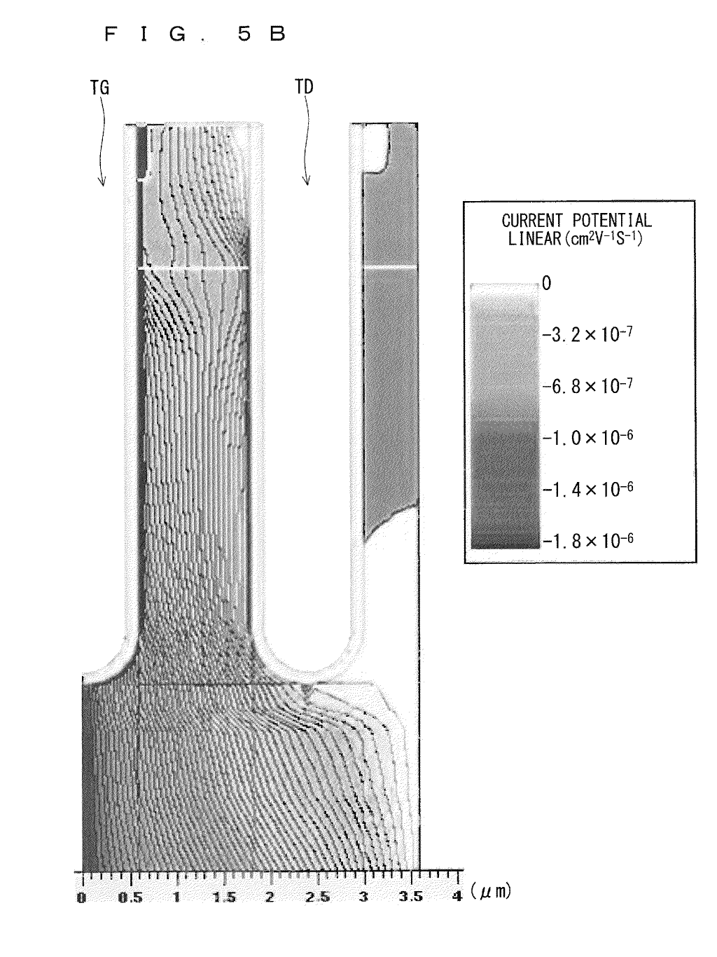

FIG. 5A shows a result of a simulation about a current potential in an ON state according to Comparative Example 1 conducted in a region corresponding to a dashed area V (FIG. 3). Unlike in the IGBT of the embodiment, in an IGBT of Comparative Example 1, the damping trench area contact hole 12D is provided in the same position as the MOS area contact hole 12T in terms of the direction DX (FIG. 2B). More specifically, in the IGBT of Comparative Example 1, both the MOS area contact hole 12T and the damping trench area contact hole 12D are provided integrally in the range A1. FIG. 5B shows an example of a result of a simulation about a current potential in an ON state according to Working Example conducted in the dashed area V (FIG. 3). Working Example (FIG. 5B) produces a current path between the gate trench TG and the damping trench TD of a density higher than that of a current path in Comparative Example 1 (FIG. 5A). This phenomenon is considered to result from the arrangement of the damping trench area contact hole 12D. In Comparative Example 1, the damping trench area contact hole 12D is arranged in the range A1 corresponding to a range where an effective gate structure is formed (structures shown in FIGS. 14 and 15 of PCT International Publication No. 02/058160 correspond to Comparative Example 1, for example). Thus, a path along which carriers pass through to lead to the aforementioned contact hole is formed between adjacent ones of the damping trenches TD. In contrast, according to Working Example, the damping trench area contact hole 12D is not arranged in the range A1. Thus, a path along which carriers pass through is not formed between adjacent ones of the damping trenches TD. A path along which carriers pass through is formed only between the gate trench TG and the damping trench TD accordingly, thereby producing the current path of a higher density between the gate trench TG and the damping trench TD.

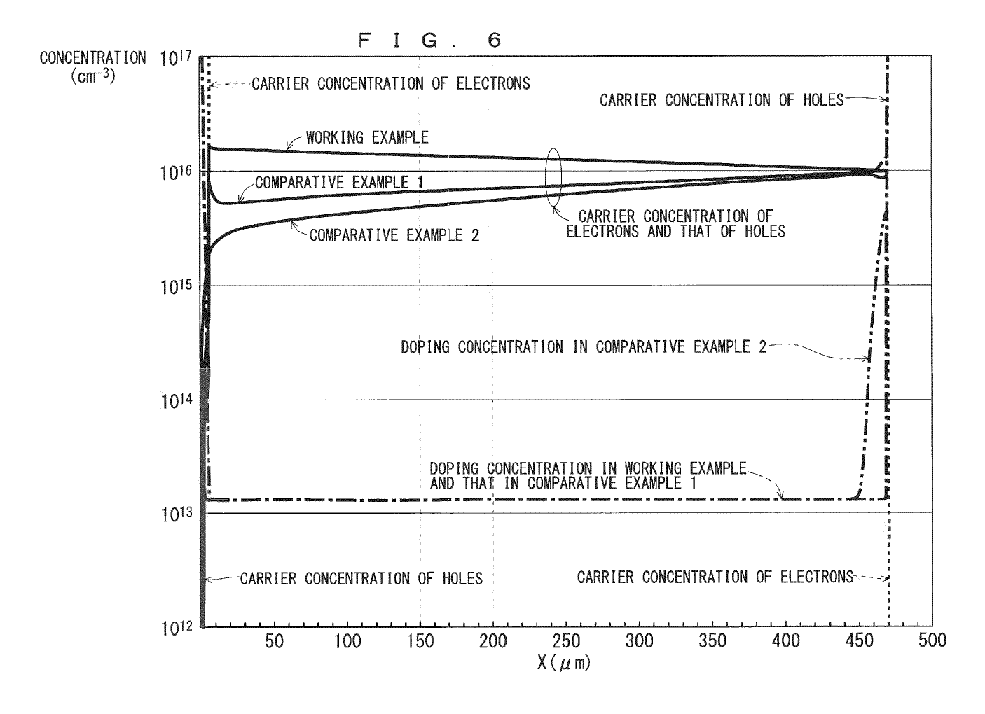

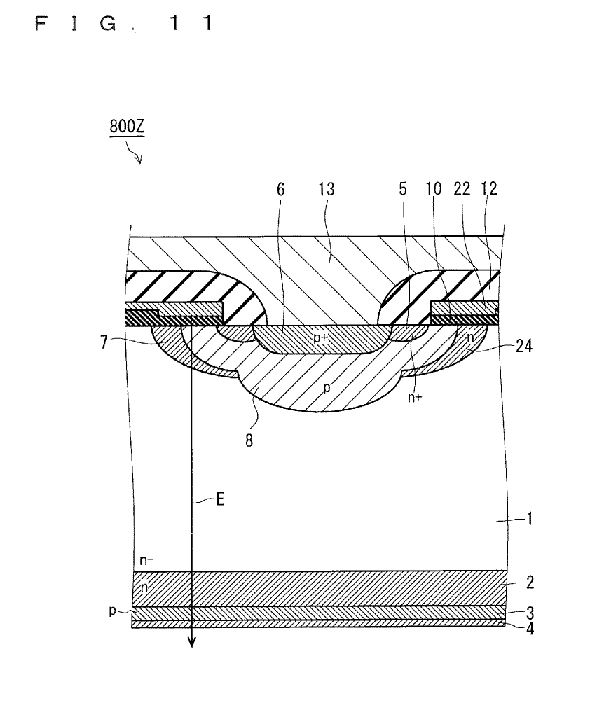

FIG. 6 shows a carrier concentration of electrons, a carrier concentration of holes, and a doping concentration in an ON state in terms of a depth X in each of a direction D (FIG. 3) of Working Example, a direction of Comparative Example 1 corresponding to the direction D (FIG. 3), and a direction E of Comparative Example 2. Comparative Example 2 is an IGBT 800Z (FIG. 11) of a planar type and not of a trench type. These carrier concentration distributions show that in a region from the n⁺-emitter layer 5 to the n⁻-drift layer 1 on a shallow side (substantially the left half of the drawing), a carrier concentration of Working Example is higher than those of Comparative Examples 1 and 2.

As understood from these results, an increased impurity concentration in the n⁻-drift layer 1 in an ON state according to Working Example is considered to contribute to reduction in an ON voltage of an IGBT.

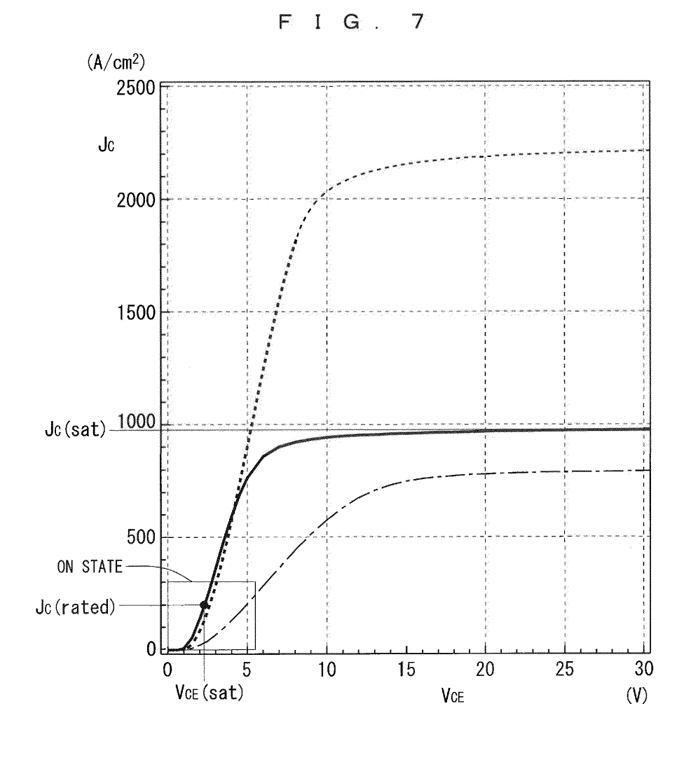

FIG. 7 shows a relationship between a collector-emitter voltage V_{CE} and a collector current density J_{C} in each of Working Example (solid line), Comparative Example 2 (alternate long and short dashed line), and Comparative Example 3 (dashed line). Comparative Example 3 is an IGBT where all trenches are formed of the gate trenches TG spaced with the trench pitch W_{TP} in the absence of the damping trench TD (FIG. 3). According to Working Example (solid line), the aforementioned mechanism described by referring to FIGS. 5 and 6 functions to reduce an ON voltage (a saturation voltage V_{CE}(sat) with a rated current density J_{C} (rated)). Additionally, according to Working Example, the presence of the damping trench TD reduces the number of the gate trenches TG accordingly, compared to Comparative Example 3. This reduces an effective gate width per unit area in a plan view (in the field of view of FIG. 2D).

An equivalent circuit of an IGBT while the IGBT is in an ON state can be expressed using a series connection between a pn diode and an MISFET (Metal insulator Semiconductor Field Effect Transistor). A saturation region of the output characteristics of the IGBT (right side region on the graph of FIG. 7) is expressed by using the following formula showing a saturation current I_{C} of the MISFET:

$${I}_{C} = \frac{1}{2} \frac{W}{L} {μ}_{eff} {{C}_{0 X} ( {V}_{GE} - {V}_{GE} ( th ) )}^{2} \qquad [ Formula 1 ]$$

where W is a gate width, L is a channel length, μ_{eff} is effective mobility, C_{0X} is the capacitance of a gate insulating film, V_{GE} is a gate-emitter voltage, and V_{GE}(th) is a threshold voltage. The saturation current I_{C} is reduced with reduction in the gate width W.

As described above, an effective gate width is smaller in Working Example than in Comparative Example 3. As a result, a saturation current density J_{C}(sat) is reduced while the IGBT is shorted. As understood from these, Working Example is a power semiconductor device achieving both reduction in the ON voltage V_{CE}(sat) and reduction in the saturation current density J_{C}(sat).

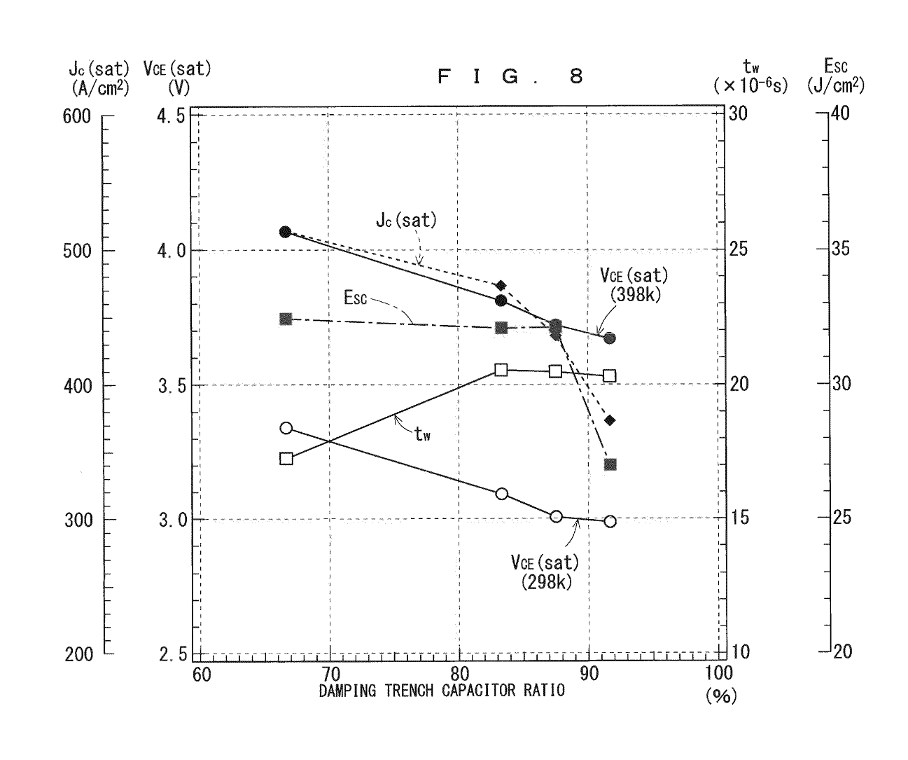

The effectiveness of this embodiment from a different aspect is described next. FIG. 8 shows a relationship of a damping trench capacitor ratio with each of the saturation current density J_{C}(sat), the ON voltage V_{CE}(sat), a maximum interrupt gate voltage pulse width t_{w} and a maximum interrupt energy density E_{SC} in a shorted state according to Working Example having a 4500 V-class breakdown voltage. The maximum interrupt energy density E_{SC} is obtained by time-integrating the product of the saturation current density J_{C}(sat) and the collector-emitter voltage V_{CE} during an interrupting operation. The damping trench capacitor ratio is a ratio of the number of the damping trenches TD to the total number of the gate trenches TG and the damping trenches TD in a unit cell. In the case of FIG. 2D, for example, one gate trench TG and seven damping trenches TD form one unit cell. Thus, the damping trench capacitor ratio is determined as {7/(1+7)}×100=87.5(%). The maximum interrupt gate voltage pulse width t_{w} and the maximum interrupt energy density E_{SC} are indexes to the performance of an IGBT while the IGBT is shorted.

According to Working Example, an effective gate width per unit area of a device can be adjusted using the damping trench capacitor ratio. Specifically, an effective gate width per unit area is reduced by increasing this ratio. A characteristic to achieve both low V_{CE}(sat) and low J_{C}(sat) depends on the damping trench capacitor ratio. Thus, an index to the performance of an IGBT while the IGBT is shorted also depends on the damping trench capacitor ratio. With increase in the damping trench capacitor ratio, the index to the performance of the IGBT while the IGBT is shorted tends to increase. The ON voltage V_{CE}(sat) is reduced with increase in the damping trench capacitor ratio. This is for the reason that, as the damping trench capacitor ratio increases, a carrier concentration increases in the region from the n⁺-emitter layer 5 toward the n⁻-drift layer 1 in the IGBT 800 (substantially the left half on the graph of FIG. 6), as shown in FIGS. 5 and 6. As understood from above, according to this embodiment, a power semiconductor device achieving both low V_{CE}(sat) and low J_{C}(sat) is obtained by determining the damping trench capacitor ratio properly.

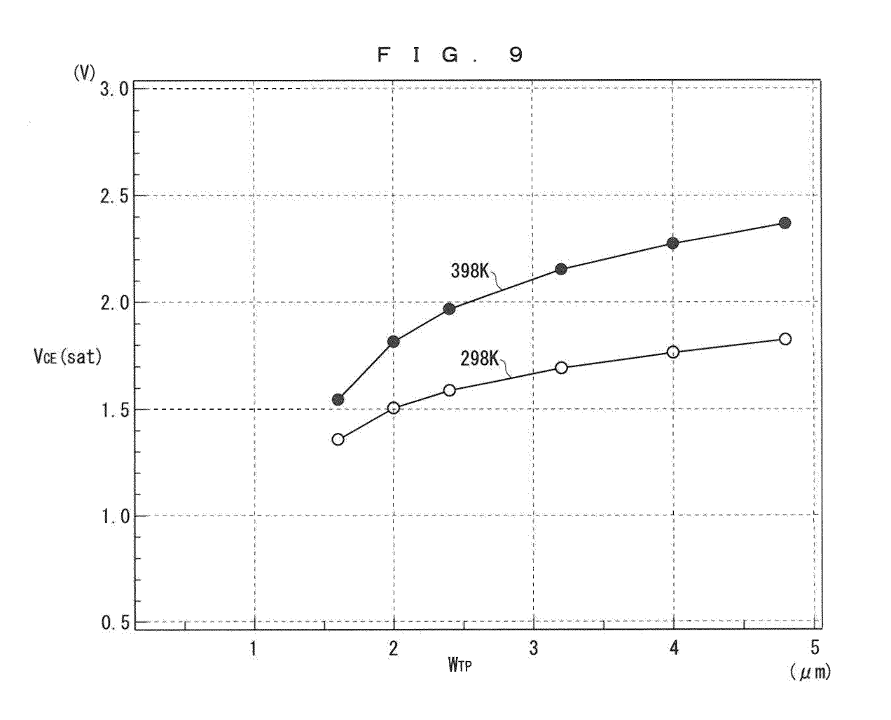

Referring to FIG. 9, the ON voltage V_{CE}(sat) can also be reduced by reducing the trench pitch W_{TP} (FIG. 3). Reduction in W_{TP} reduces V_{CE}(sat) as it increases a carrier concentration on an emitter side (left side of FIG. 6), as shown in FIG. 6.

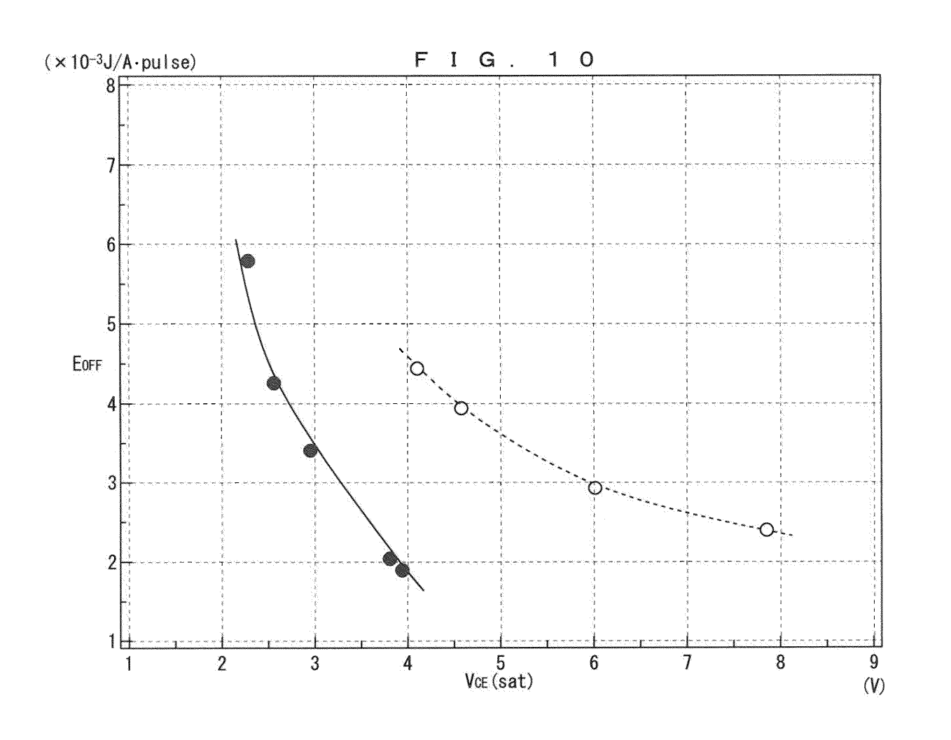

FIG. 10 shows a trade-off relationship between the ON voltage V_{CE}(sat) and turn-off loss E_{OFF} in each of Working Example (solid line) and Comparative Example 2 (dashed line) of FIG. 11. Total loss determined while an IGBT operates depends on both the ON voltage V_{CE}(sat) and the turn-off loss E_{OFF}. The total loss is reduced with reduction in the respective values of the ON voltage V_{CE}(sat) and the turn-off loss E_{OFF}. As seen from FIG. 10, according to Working Example, the aforementioned trade-off relationship is improved considerably compared to Comparative Example 2 corresponding to the planar IGBT.

In summary, this embodiment is capable of enhancing an index to the performance of an IGBT while the IGBT is shorted as described by referring to FIG. 8 while being capable of reducing total loss by improving the trade-off relationship between the ON voltage V_{CE}(sat) and the turn-off loss E_{OFF} as described by referring to FIG. 10.

In the aforementioned embodiment, the gate connection 22G (FIG. 2C) may be omitted. In this case, the plurality of gate electrodes 22 (FIG. 2C) provided in corresponding ones of the plurality of gate trenches TG (FIG. 2D) may be connected to each other through the gate contact 28G (FIG. 2E) of the surface gate wiring part 28. The capacitor connection 23D (FIG. 2C) may be omitted. In this case, the plurality of capacitor electrodes 23 (FIG. 2C) provided in corresponding ones of the plurality of damping trenches TD (FIG. 2D) may be connected to each other through the damping contact 13D (FIG. 2E).

The n-layer 24 may be omitted from the “first region” including the n⁻-drift layer 1 and the n-layer 24 (FIGS. 3 and 4). In this case, the p-base layer 8 can be provided directly on the n⁻-drift layer 1.

The emitter electrode 13 (FIGS. 3 and 4) may have a multilayer structure. For example, the emitter electrode 13 may include a barrier metal layer or an ohmic contact layer provided on a side facing the substrate SB.

The IGBT 800 of this embodiment is suitable particularly for a high breakdown voltage in a class from about 3300 to about 6500 V. However, the level of a breakdown voltage of a power semiconductor device is not particularly limited.

A semiconductor material for the substrate SB is not limited to silicon (Si). The substrate SB may also be made of a wide band gap material such as silicon carbide (SiC) or gallium nitride (GaN), for example. The n-type and the p-type, described as the first and second conductivity types respectively, can alternatively be the second and first conductivity types respectively.

The embodiment of the present invention can be modified or omitted, where appropriate, within the scope of the invention. While the invention has been shown and described in detail, the foregoing description is in all aspects illustrative and not restrictive. It is therefore understood that numerous modifications and variations can be devised without departing from the scope of the invention.

### REFERENCE SIGNS LIST

1 n⁻-drift layer (First region)

2 n-buffer layer

3 p-collector layer

4 Collector electrode (First main electrode)

5 n⁺-emitter layer (Third region)

6 p⁺-layer

8 p-base layer (Second region)

10 Trench insulating film

12 Interlayer insulating film

12D Damping trench area contact hole (Second contact hole)

12G Gate contact hole (Third contact hole)

12T MOS area contact hole (First contact hole)

13 Emitter electrode (Second main electrode)

13D Damping contact

13T MOS area contact

15 Passivation layer

22 Gate electrode

22G Gate connection

23 Capacitor electrode

23D Capacitor connection

24 n-layer (First region)

28 Surface gate wiring part

28G Gate contact

29 Gate pad

800 IGBT (Power semiconductor device)

A1 to A3 Ranges (First to third ranges)

DX Direction (One direction)

S1 Lower surface (First surface)

S2 Upper surface (Second surface)

SB Substrate (Semiconductor substrate)

TD Damping trench (Second trench)

TG Gate trench (First trench)

1. A power semiconductor device comprising:
a semiconductor substrate having a first surface and a second surface opposite said first surface, said semiconductor substrate including a first region having a first conductivity type, a second region provided on said first region and having a second conductivity type different from said first conductivity type, and a third region provided on said second region and arranged in said second surface and having said first conductivity type, said second surface being provided with a plurality of first trenches and a plurality of second trenches, said first trenches facing said first to third regions;
a first main electrode provided on said first surface of said semiconductor substrate;
a trench insulating film covering said first trenches and said second trenches of said semiconductor substrate;
a gate electrode having parts buried in said first trenches with said trench insulating film therebetween;
a capacitor electrode having parts buried in said second trenches with said trench insulating film therebetween;
an interlayer insulating film provided on said second surface and having a first contact hole and a second contact hole; and
a second main electrode provided on said interlayer insulating film, contacting said third region through said first contact hole, and contacting said capacitor electrode through said second contact hole, wherein
said second surface of said semiconductor substrate has a first range in one direction on said second surface and a second range out of said first range toward said one direction,
each of said first trenches and each of said second trenches cross said first range in said one direction,
regarding said first and second ranges, said first contact hole is located only in said first range and said second contact hole is located only in said second range,
said second surface of said semiconductor substrate has a third range out of said second range toward said one direction,
said first trenches extend from said first range into said third range through said second range, and
said second trenches each have an end portion located in said second range.

2. (canceled)

3. The power semiconductor device according to claim 1, wherein said interlayer insulating film has a third contact hole located in said third range,
said power semiconductor device further comprising a gate wiring part provided on said interlayer insulating film and contacting said gate electrode through said third contact hole.

4. The power semiconductor device according to claim 1, wherein said capacitor electrode has a capacitor connection through which parts of said capacitor electrode buried in at least adjacent two of said second trenches are connected to each other.

5. The power semiconductor device according to claim 4, wherein said second contact hole is arranged on said capacitor connection.
